(19) United States
(12) Patent Application Publication
(10) Pub. No.: US 2026/0369953 A1
(43) Pub. Date: Nov. 19, 2026

(54) LASER APPARATUS, IRRADIATION METHOD, AND ELECTRONIC DEVICE MANUFACTURING METHOD

(71) Applicant: Gigaphoton Inc., Tochigi (JP)

(72) Inventors: Mayu HASEGAWA, Oyama-shi (JP); Takahito KUMAZAKI, Oyama-shi (JP)

(73) Assignee: Gigaphoton Inc., Tochigi (JP)

(21) Appl. No.: 19/637,516

(22) Filed: Apr. 2, 2026

(30) Foreign Application Priority Data
May 15, 2025 (JP) 2025-082193

(51) Int. Cl. H01S 3/105; G03F 7/00; G03F 7/20; H01S 3/00; H01S 3/23

(52) U.S. Cl. CPC H01S 3/105; G03F 7/2004; G03F 7/70025; G03F 7/70041; G03F 7/70525; H01S 3/0057; H01S 3/2308

(57) ABSTRACT

A laser apparatus according to an aspect of the present disclosure includes: an oscillator configured to output pulse laser light; an optical element disposed in an optical path of the pulse laser light and having at least one slit formed in a surface irradiated with the pulse laser light; and a moving mechanism configured to move the optical element.

### CROSS-REFERENCE TO RELATED APPLICATIONS

The present application claims the benefit of Japanese Patent Application No. 2025-082193, filed on May 15, 2025, the entire contents of which are hereby incorporated by reference.

### BACKGROUND

### 1. Technical Field

The present disclosure relates to a laser apparatus, an irradiation method, and an electronic device manufacturing method.

### 2. Related Art

In recent years, a semiconductor exposure apparatus is required to improve the resolution thereof as semiconductor integrated circuits are increasingly miniaturized and highly integrated. To this end, reduction in the wavelength of light emitted from a light source for exposure is underway. For example, a KrF excimer laser apparatus, which outputs laser light having a wavelength of about 248 nm, and an ArF excimer laser apparatus, which outputs laser light having a wavelength of about 193 nm, are used as a gas laser apparatus for exposure.

The light from KrF and ArF excimer laser apparatuses performing spontaneous laser oscillation has a wide spectral linewidth in a range between 350 and 400 pm. A projection lens made of a material that transmits ultraviolet light, such as KrF and ArF laser light, therefore produces chromatic aberrations in some cases. As a result, the resolution of the projection lens may decrease. To avoid the decrease in the resolution, the spectral linewidth of the laser light output from the gas laser apparatus needs to be narrow enough to make the chromatic aberrations negligible. To this end, a line narrowing module (LNM) including a line narrowing element (such as etalon or grating) is provided in some cases in an optical resonator of the gas laser apparatus to narrow the spectral linewidth. A gas laser apparatus providing a narrowed spectral linewidth is hereinafter referred to as a line-narrowed gas laser apparatus.

### CITATION LIST

### Patent Literature

[PTL 1] U.S. Patent application Publication No. 2024/0146011

### SUMMARY

A laser apparatus according to an aspect of the present disclosure includes: an oscillator configured to output pulse laser light; an optical element disposed in an optical path of the pulse laser light and having at least one slit formed in a surface irradiated with the pulse laser light; and a moving mechanism configured to move the optical element.

An irradiation method according to another aspect of the present disclosure is an irradiation method using a laser apparatus including an oscillator configured to output pulse laser light, an optical element disposed in an optical path of the pulse laser light and having at least one slit formed in a surface irradiated with the pulse laser light, and a moving mechanism configured to move the optical element, the method including: irradiating a first region of the optical element with the pulse laser light; controlling the moving mechanism to move the optical element in a way that a second region separated from the first region by the at least one slit is irradiated with the pulse laser light, and irradiating the second region with the pulse laser light.

An electronic device manufacturing method according to another aspect of the present disclosure includes: outputting pulse laser light from a laser apparatus to an exposure apparatus; and exposing a photosensitive substrate to the pulse laser light in the exposure apparatus to manufacture electronic devices, the laser apparatus including an oscillator configured to output the pulse laser light, an optical element disposed in an optical path of the pulse laser light and having at least one slit formed in a surface irradiated with the pulse laser light, and a moving mechanism configured to move the optical element.

### BRIEF DESCRIPTION OF DRAWINGS

Some embodiments of the present disclosure will be described below only by way of example with reference to the accompanying drawings.

FIG. 1 schematically shows the configuration of a laser apparatus according to Comparative Example.

FIG. 2 is a front view of an output-side holding unit.

FIG. 3 is a side view of the output-side holding unit.

FIG. 4 is a front view of a moving mechanism.

FIG. 5 is a cross-sectional view of the moving mechanism taken along the line A-A in FIG. 4.

FIG. 6 shows the operation of changing an irradiation region at an output coupling mirror.

FIG. 7 shows the operation of changing an irradiation region at a beam splitter.

FIG. 8 shows expansion of a degraded region caused by radiation.

FIG. 9 shows the configurations of an output-side holding unit and an output coupling mirror according to a first embodiment.

FIG. 10 is a front view of the output coupling mirror according to the first embodiment.

FIG. 11 is a cross-sectional view of the output coupling mirror taken along the line B-B in FIG. 10.

FIG. 12 shows the positional relationship between slits and an irradiation spot.

FIG. 13 shows the process procedure in which a laser processor controls a moving mechanism.

FIG. 14 shows a state in which the slits prevent expansion of a degraded region.

FIG. 15 is a front view of an output coupling mirror having three slits formed therein.

FIG. 16 shows the configuration of an output coupling mirror according to a first variation.

FIG. 17 shows the configuration of an output coupling mirror according to a second variation.

FIG. 18 is a front view of a holder holding a beam splitter according to a second embodiment.

FIG. 19 is a cross-sectional view of the holder taken along the line E-E in FIG. 18.

FIG. 20 is a cross-sectional view of the holder taken along the line F-F in FIG. 18.

FIG. 21 is a front view of the holder.

FIG. 22 shows another exemplary form of an optical pulse stretcher.

FIG. 23 schematically shows an example of the configuration of an exposure apparatus.

### DETAILED DESCRIPTION

### Contents

1. Comparative Example
   1.1 Configuration
   1.2 Operation
   1.3 Problems
2. First Embodiment
   2.1 Configuration
   2.2 Operation
   2.3 Advantages
   2.4 Variations
3. Second Embodiment
   3.1 Configuration
   3.2 Operation
   3.3 Advantages
4. Another Exemplary Form of OPS
5. Electronic Device Manufacturing Method
6. Examples of Configuration of Laser Processor

Embodiments of the present disclosure will be described below in detail with reference to the drawings. The embodiments described below show some examples of the present disclosure and are not intended to limit the contents of the present disclosure. Furthermore, all configurations and operations described in the embodiments are not necessarily essential as configurations and operations in the present disclosure. The same elements have the same reference characters, and no redundant description of the same elements will be made.

### 1. Comparative Example

Comparative Example of the present disclosure is an aspect that the applicant is aware of as known only by the applicant, and is not a publicly known example that the applicant is self-aware of.

### 1.1 Configuration

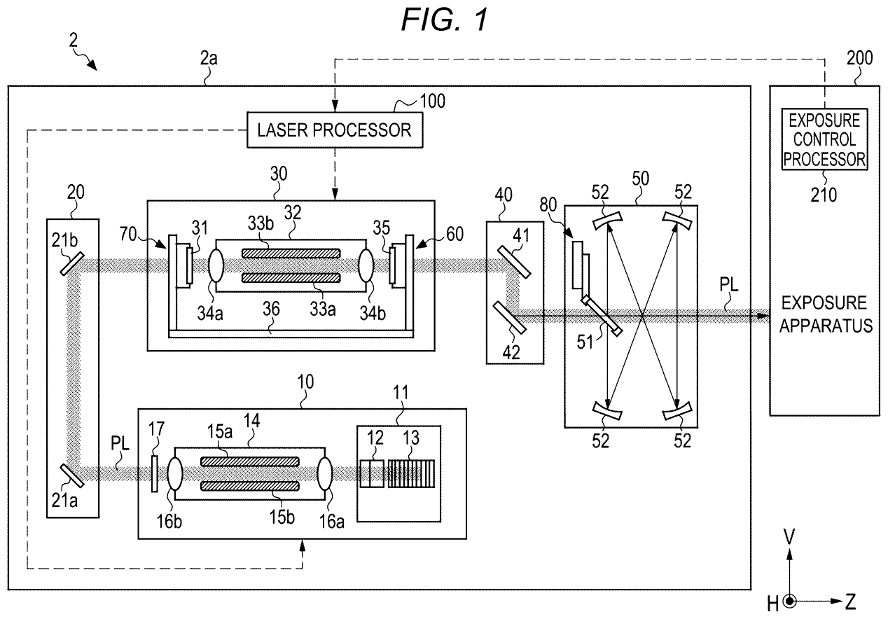

FIG. 1 schematically shows the configuration of a laser apparatus 2 according to Comparative Example. The laser apparatus 2 is a discharge-excitation-type, line-narrowed gas laser apparatus including a master oscillator (MO) 10, an MO beam steering unit 20, a power oscillator (PO) 30, a PO beam steering unit 40, an optical pulse stretcher (OPS) 50, and a laser processor 100.

The MO 10, the MO beam steering unit 20, the PO 30, the PO beam steering unit 40, the OPS 50, and the laser processor 100 are housed in an enclosure 2a.

The MO 10 includes a line narrowing module (LNM) 11, a chamber 14, and an output coupling mirror (OC) 17, and outputs pulse laser light PL. The MO 10 is an example of the “oscillator” according to the technology described in the present disclosure.

The LNM 11 includes a prism beam expander 12 and a grating 13, which narrow the spectral linewidth. The prism beam expander 12 and the grating 13 are disposed in the Littrow arrangement, which causes the angle of incidence of the light incident on the grating 13 to be equal to the angle of diffraction of the light diffracted by the grating 13.

The OC 17 is a partially reflective mirror and is so disposed that the OC 17 and the LNM 11 form an optical resonator. The reflectance of the OC 17 is, for example, in a range between 40% and 60%. The OC 17 is an example of a “mirror provided in an optical resonator of the oscillator” according to the technology described in the present disclosure.

The chamber 14 is disposed in the optical path of the optical resonator. The chamber 14 includes a pair of discharge electrodes 15a and 15b and two windows 16a and 16b, through which the pulse laser light PL passes. The chamber 14 houses an excimer laser gas. The excimer laser gas may contain, for example, an Ar or Kr gas as a rare gas, an F₂ gas as a halogen gas, and a Ne gas as a buffer gas.

The MO beam steering unit 20 includes highly reflective mirrors 21a and 21b. The highly reflective mirrors 21a and 21b are so disposed that the pulse laser light PL output from the MO 10 enters the PO 30. A highly reflective mirror in the present disclosure is, for example, a planar mirror including a substrate made of synthetic quartz or calcium fluoride (CaF₂) and a highly reflective film formed at a surface of the substrate. The highly reflective film is a dielectric multilayer film, for example, a film containing fluoride.

The PO 30 includes a rear mirror 31, a chamber 32, and an OC 35. The rear mirror 31 and the OC 35 are arranged so as to constitute an optical resonator. The PO 30 is an example of the “amplifier” according to the technology described in the present disclosure. The OC 35 and the rear mirror 31 are an example of a “mirror provided in an optical resonator of the amplifier” according to the technology described in the present disclosure.

The chamber 32 is disposed in the optical path of the optical resonator. The chamber 32 may be configured in the same manner as the chamber 14 of the MO 10. That is, the chamber 32 includes a pair of discharge electrodes 33a and 33b, and two windows 34a and 34b, through which the pulse laser light PL passes. The chamber 32 houses an excimer laser gas.

The rear mirror 31 is a partially reflective mirror having reflectance in a range between 50% and 90%. The OC 35 is a partially reflective mirror having reflectance in a range between 10% and 30%.

The PO 30 further includes a support member 36, an output-side holding unit 60, and a rear-side holding unit 70. The support member 36 is a planar plate that is longer than the chamber 32 and extends in the traveling direction of the pulse laser light PL. The output-side holding unit 60 is disposed at one end of the support member 36 and holds the OC 35. The rear-side holding unit 70 is disposed at the other end of the support member 36 and holds the rear mirror 31.

The support member 36, the output-side holding unit 60, and the rear-side holding unit 70 position the OC 35 between the window 34b and the PO beam steering unit 40, and position the rear mirror 31 between the window 34a and the MO beam steering unit 20. The configurations of the output-side holding unit 60 and the rear-side holding unit 70 will be described later.

The PO beam steering unit 40 includes highly reflective mirrors 41 and 42. The highly reflective mirror 41 is disposed to reflect the pulse laser light PL output from the PO 30 to cause the reflected pulse laser light PL to be incident on the highly reflective mirror 42. The highly reflective mirror 42 is disposed to reflect the pulse laser light PL reflected off the highly reflective mirror 41 to cause the reflected pulse laser light PL to enter the OPS 50.

The OPS 50 includes a beam-splitter (BS) 51 and multiple concave mirrors 52. The BS 51 is disposed in the optical path of the pulse laser light PL reflected off the highly reflective mirror 42. The BS 51 is a partially reflective mirror that transmits part of the incident pulse laser light PL and reflects the other part thereof. The reflectance of the BS 51 is preferably in a range between 40% and 70%, and is more preferably about 60%.

The multiple concave mirrors 52 constitute a looped optical path that circulates part of the pulse laser light PL reflected off the BS 51 to return the circulated light to the BS 51. Part of the pulse laser light PL incident from the highly reflective mirror 42 and having passed through the BS 51 and part of the pulse laser light PL having circulated along the looped optical path at least once and then reflected off the BS 51 are superimposed on each other. The pulse width of the pulse laser light PL is thus extended.

The OPS 50 further includes a moving mechanism 80, which moves the BS 51. The configuration of the moving mechanism 80 will be described later.

An exposure apparatus 200 as an external apparatus is coupled to the laser apparatus 2, and the pulse laser light PL output from the OPS 50 enters the exposure apparatus 200. The exposure apparatus 200 is provided with an exposure control processor 210. The exposure control processor 210 is coupled to the laser processor 100.

The laser processor 100 is coupled to the exposure control processor 210, the MO 10, and the PO 30.

A monitoring module that is not shown may be disposed in the optical path of the pulse laser light PL output from the OPS 50. The monitoring module detects the number of passes of the pulse laser light PL and measures the pulse energy, spectral linewidth, wavelength, and other parameters of the pulse laser light PL.

In the present disclosure, the direction of discharge induced by the discharge electrodes 33a and 33b is called a V direction, and the direction parallel to the optical path axis of the pulse laser light PL output from the PO 30 is called a Z direction. The direction perpendicular to the V and Z directions is called an H direction. In the present disclosure, the term “parallel” is not limited to a parallel state in a geometrically perfect manner, and includes the concept of “substantially parallel” allowing practically acceptable angular errors. Similarly, the term “perpendicular” is not limited to a perpendicular state in a geometrically perfect manner, and includes the concept of “substantially perpendicular” allowing practically acceptable angular errors.

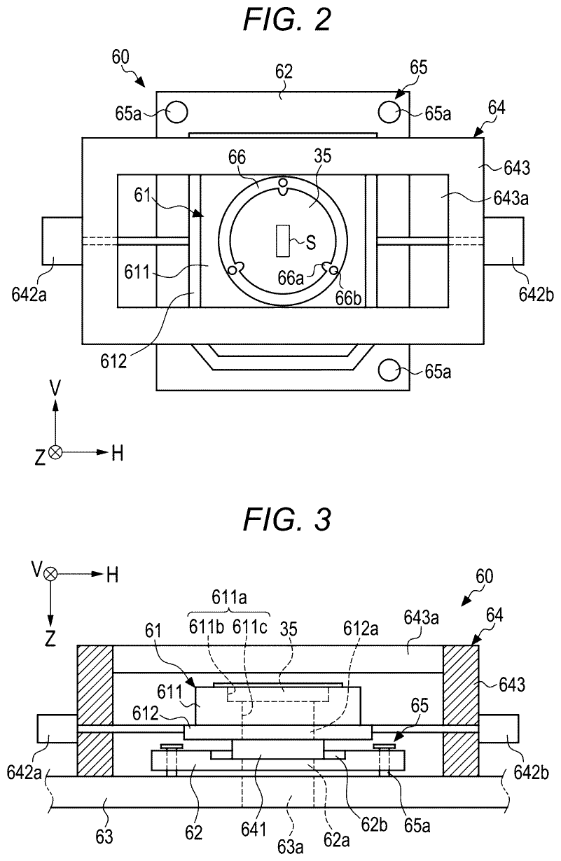

FIGS. 2 and 3 show the configuration of the output-side holding unit 60. FIG. 2 is a front view of the output-side holding unit 60. FIG. 3 is a side view of the output-side holding unit 60. In FIG. 3, a portion of a case 643 is shown in cross-section.

The output-side holding unit 60 includes a holder 61, a base member 62, a support member 63, a moving mechanism 64, and an angle maintaining mechanism 65. The holder 61 is disposed at the base member 62 while holding the OC 35. The support member 63 supports the base member 62. Note that FIG. 2 does not show the support member 63.

The holder 61 includes a body portion 611, which holds the OC 35, and an attachment plate 612, to which the body portion 611 is attached. The body portion 611 is provided with a through hole 611a, through which the pulse laser light PL passes. The through hole 611a has a circular large-diameter portion 611b and a circular small-diameter portion 611c. The large-diameter portion 611b is located at a position closer to the window 34b than the small-diameter portion 611c and communicates with the small-diameter portion 611c. The diameter of the large-diameter portion 611b is greater than the diameter of the small-diameter portion 611c, and the large-diameter portion 611b is approximately as large as the OC 35. The OC 35 is disposed in the large-diameter portion 611b.

The attachment plate 612, the base member 62, and the support member 63 are provided with circular through holes 612a, 62a, and 63a, respectively. The through hole 612a communicates with the small-diameter portion 611c and the through hole 62a, and the through hole 62a communicates with the through hole 63a.

An annular leaf spring 66, which presses down a circumferential edge portion of the OC 35, is disposed at the surface of the body portion 611 of the holder 61. The leaf spring 66 is provided with multiple claws 66a, which press down the circumferential edge portion of the OC 35. The leaf spring 66 is attached to the body portion 611 with multiple screws 66b. In the example shown in FIG. 2, three claws 66a are provided, and the screws 66b are fastened into screw holes that are not shown but are provided in the body portion 611.

The moving mechanism 64 includes a guide unit 641, cylinders 642a and 642b, and the case 643. The guide unit 641 is a linear guide that is disposed between the holder 61 and the base member 62 and movably supports the holder 61. Specifically, the guide unit 641 includes a rail that is not shown but is provided at the rear surface of the attachment plate 612, and a slider that is not shown but is provided in a groove 62b formed in the base member 62. The guide unit 641 and the groove 62b are provided at positions where they do not overlap with the through hole 62a or 63a.

The cylinders 642a and 642b have shafts that extend in the H direction and sandwich the attachment plate 612 from opposite sides. The front end of the shaft of the cylinder 642a is coupled to one side surface of the attachment plate 612, and the front end of the shaft of the cylinder 642b is coupled to the opposite side surface of the attachment plate 612.

When the cylinders 642a and 642b are operated, the shafts thereof move in conjunction with each other in the H direction, so that the OC 35 moves together with the holder 61 in the H direction. Moving the OC 35 as described above allows a change in the position of an irradiation spot S of the pulse laser light PL with which the OC 35 is irradiated. Changing the position of the irradiation spot S can suppress concentrated irradiation of a certain region of the OC 35 with the pulse laser light PL.

The case 643 is disposed at the support member 63 and surrounds the body portion 611, the attachment plate 612, and the base member 62. An opening 643a, via which the pulse laser light PL enters the OC 35, is formed in the upper surface of the case 643. The cylinders 642a and 642b are fixed to side surfaces of the case 643, and the shafts of the cylinders 642a and 642b pass through the side surfaces of the case 643.

The angle maintaining mechanism 65 is a mechanism that maintains a predetermined inclination angle of the holder 61 with respect to the support member 63. For example, multiple adjustment screws 65a are used as the angle maintaining mechanism 65. The adjustment screws 65a are screwed into screw holes formed in the base member 62, and front end portions of the adjustment screws 65a engage with screw holes formed in the support member 63. The inclination of the base member 62 with respect to the support member 63 is adjusted by the amount by which each of the adjustment screws 65a is screwed. The inclination angle of the OC 35 is thus adjusted to and maintained at a predetermined angle.

The rear-side holding unit 70 may be configured in the same manner as the output-side holding unit 60. That is, the rear-side holding unit 70 may be so configured that the rear mirror 31 is movable in a direction perpendicular to the optical path axis of the pulse laser light PL.

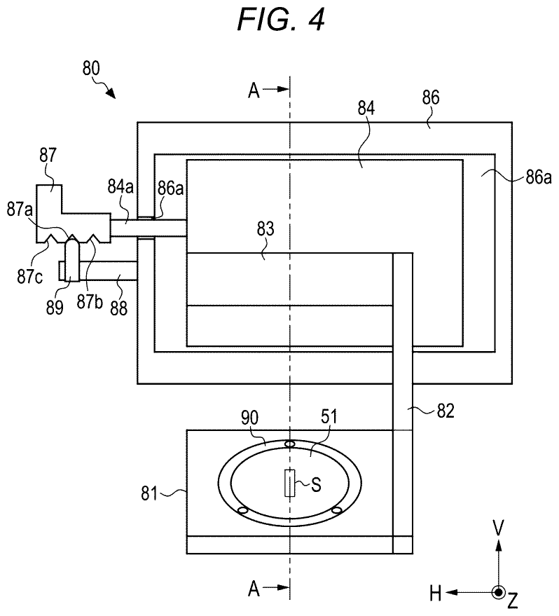

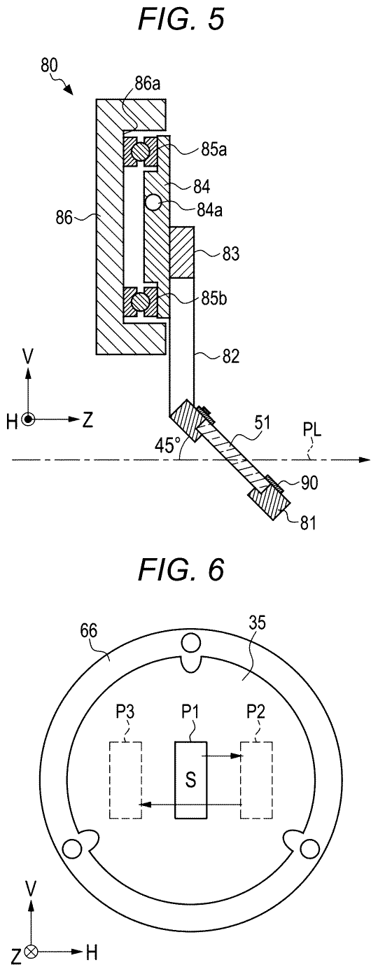

FIGS. 4 and 5 show the configuration of the moving mechanism 80. FIG. 4 is a front view of the moving mechanism 80. FIG. 5 is a cross-sectional view of the moving mechanism taken along the line A-A in FIG. 4.

The moving mechanism 80 includes a holder 81, which holds the BS 51, an arm 82, an attachment plate 83, a plate 84, linear guides 85a and 85b, and a case 86. The BS 51 is held by the holder 81 with the front surface of the BS 51 inclined at 45°with respect to the optical path axis of the pulse laser light PL. The BS 51 has a circular shape, and has a circumferential edge portion pressed down by an annular leaf spring 90. The leaf spring 90 is configured in the same manner as the leaf spring 66 described above.

The holder 81 is attached to one end of the arm 82. The other end of the arm 82 is attached to the attachment plate 83. The attachment plate 83 is fixed to the plate 84. The linear guides 85a and 85b extend in the H direction and are disposed at a reference plane 86a of the case 86. The plate 84 is supported by the linear guides 85a and 85b in a movable manner in the H direction.

A rod 84a extending in the H direction is coupled to the plate 84. The rod 84a extends out of the case 86 through a through hole 86b formed in the case 86, and allows the plate 84 to move in the H direction when receiving a force external to the case 86. A handle 87 is provided at the end of the rod 84a extending out of the case 86. Multiple positioning grooves 87a, 87b, and 87c, which define a position in the direction in which the handle 87 is moved, are formed in the handle 87.

A support member 88 is coupled to the exterior of the case 86, and a plunger 89 is attached to the support member 88. The plunger 89 engages with any one of the multiple positioning grooves 87a, 87b, and 87c to position the BS 51 in the H direction via the plate 84. Moving the BS 51 by operating the handle 87 allows a change in the position of the irradiation spot S of the pulse laser light PL radiated to the BS 51. Changing the position of the irradiation spot S can suppress concentrated irradiation of a certain region of the BS 51 with the pulse laser light PL.

### 1.2 Operation

The operation of the laser apparatus 2 according to Comparative Example will next be described. First, when the laser processor 100 receives a light emission trigger from the exposure control processor 210, a power supply that is not shown applies high-voltage pulses to the gap between the discharge electrodes 15a and 15b of the MO 10.

When discharge occurs between the discharge electrodes 15a and 15b, the laser gas is excited, and the optical resonator configured with the OC 17 and the LNM 11 causes laser oscillation. The line-narrowed pulse laser light PL is therefore output via the OC 17. The MO beam steering unit 20 causes the pulse laser light PL to be incident as seed light on the rear mirror 31 of the PO 30.

At the timing when the seed light having passed through the rear mirror 31 enters the chamber 32, a power supply that is not shown applies high-voltage pulses to the gap between the discharge electrodes 33a and 33b. When discharge occurs between the discharge electrodes 33a and 33b, the laser gas is excited, and the seed light is amplified by the Fabry-Perot optical resonator configured with the OC 35 and the rear mirror 31, so that the amplified pulse laser light PL is output via the OC 35. The pulse laser light PL is ultraviolet light in an ultraviolet wavelength band in a range from 150 nm to 380 nm.

The pulse laser light PL output from the OC 35 enters the OPS 50 via the PO beam steering unit 40. The pulse width of the pulse laser light PL having entered the OPS 50 is extended, and the resultant pulse laser light PL is output to the exposure apparatus 200.

The operation performed to suppress the concentrated irradiation of a certain region of the OC 35 will next be described. The irradiation spot S has a rectangular shape, and has a longitudinal direction corresponding to the V direction and a widthwise direction corresponding to the H direction. Whenever the number of radiation shots reaches a fixed value, the moving mechanism 64 of the output-side holding unit 60 is operated to move the irradiation spot S in the widthwise direction thereof.

Specifically, the irradiation spot S is moved sequentially to a first region P1, a second region P2, and a third region P3, as shown in FIG. 6. The first region P1, the second region P2, and the third region P3 do not overlap each other and are set at positions separate from each other in the H direction at the surface of the OC 35. For example, when the irradiation spot S is set at the first region P1 and radiation thereto is performed for a long period, the first region P1 degrades. Accordingly, when the number of radiation shots reaches the fixed value, the irradiation spot S is changed to the second region P2. Similarly, when the number of radiation shots at the second region P2 reaches the fixed value, the irradiation spot S is changed to the third region P3. When the number of radiation shots at the third region P3 reaches the fixed value, the OC 35 or the combination of the OC 35 and the moving mechanism 64 are replaced with another.

The operation performed to suppress the concentrated irradiation of a partial region of the BS 51 will next be described. Whenever the number of radiation shots reaches a fixed value, the moving mechanism 80 is operated to move the irradiation spot S in the widthwise direction thereof, as in the case of the OC 35.

The settings of the first region P1, the second region P2, and the third region P3 at the BS 51 are the same as those described above. The first region P1 corresponds to the positioning groove 87a. The second region P2 corresponds to the positioning groove 87b. The third region P3 corresponds to the positioning groove 87c.

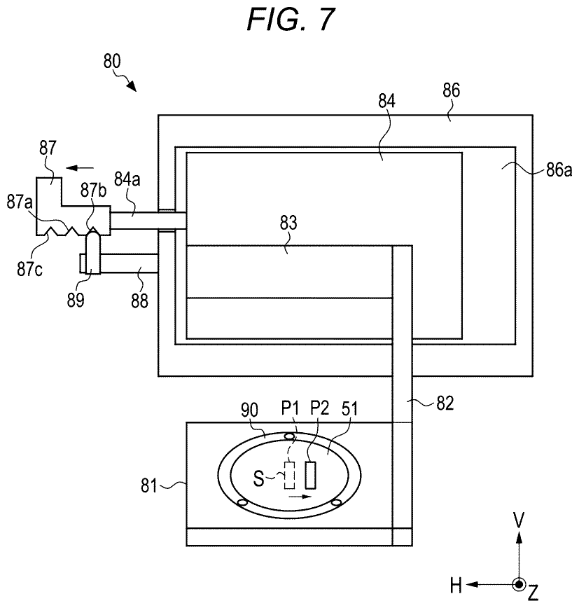

Specifically, when the number of radiation shots reaches the fixed value with the plunger 89 caused to engage with the positioning groove 87a so that the irradiation spot S is located at the first region P1, the handle 87 is operated to cause the plunger 89 to engage with the positioning groove 87b, as shown in FIG. 7. The irradiation spot S is therefore changed to the second region P2. Similarly, when the number of radiation shots at the second region P2 reaches the fixed value, the handle 87 is operated to cause the plunger 89 to engage with the positioning groove 87c. When the number of radiation shots at the third region P3 reaches the fixed value, the BS 51 or the combination of the BS 51 and the moving mechanism 80 are replaced with another.

### 1.3 Problems

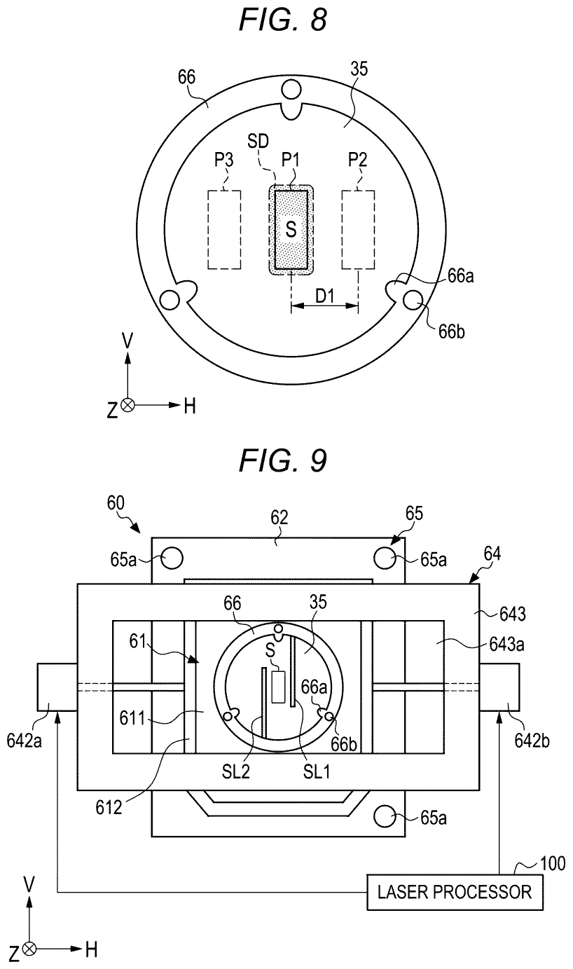

Problems with the laser apparatus 2 according to Comparative Example will next be described. In the laser apparatus 2 according to Comparative Example, degradation occurs at the first region P1 when the irradiation spot S is set at the first region P1 and the pulse laser light PL is radiated thereto, as shown in FIG. 8. The degradation progresses as the number of radiation shots increases, and a degraded region SD expands to a portion outside the first region P1.

Due to the expansion of the degraded region SD, there is a concern that the second region P2 to be irradiated next has been already degraded. As a result, it is conceivable that the laser apparatus 2 cannot sufficiently provide its performance even after the irradiation spot S is switched to another region.

To avoid the situation described above, a distance D1 between the first region P1 and the second region P2 needs to be increased in consideration of the expansion of the degradation, or the number of radiation shots at each of the regions needs to be restricted. The same holds true for the third region P3.

As described above, in Comparative Example, three irradiation regions are set at each of the OC 35 and the BS 51, and the irradiation spot S is sequentially switched from one of the irradiation regions to another whenever a predetermined number of radiation shots is reached, so that the replacement timing of the optical elements is delayed, that is, the operating life of the laser apparatus 2 is extended. To further extend the operating life, it is conceivable to increase the number of the irradiation regions, but to cope with the expansion of the degraded region SD, the distance D1 between the irradiation regions needs to be increased, so that it is difficult to increase the number of the irradiation regions. In addition, if the number of the irradiation regions is increased, it is necessary to reduce the number of radiation shots at each of the irradiation regions in order to avoid the influence of the degradation, so that the operating life cannot be extended.

An object of the present disclosure is to provide a laser apparatus 2 capable of further extending its operation life.

### 2. First Embodiment

A laser apparatus 2 according to a first embodiment of the present disclosure will be described. Note that elements that are the same as those described above have the same reference characters, and no redundant description of the same elements will be made unless otherwise they are particularly described.

### 2.1 Configuration

The laser apparatus 2 according to the present embodiment is configured in the same manner as the laser apparatus 2 according to Comparative Example except that the output-side holding unit 60 and the OC 35 are configured differently.

FIG. 9 shows the configurations of the output-side holding unit 60 and the OC 35 according to the first embodiment. The output-side holding unit 60 according to the present embodiment differs from that according to Comparative Example only in that the cylinders 642a and 642b are each a motorized cylinder including a built-in actuator and is electrically coupled to the laser processor 100. In the present embodiment, the cylinders 642a and 642b are driven and controlled by the laser processor 100. That is, the moving mechanism 64 moves the OC 35 under the control of the laser processor 100.

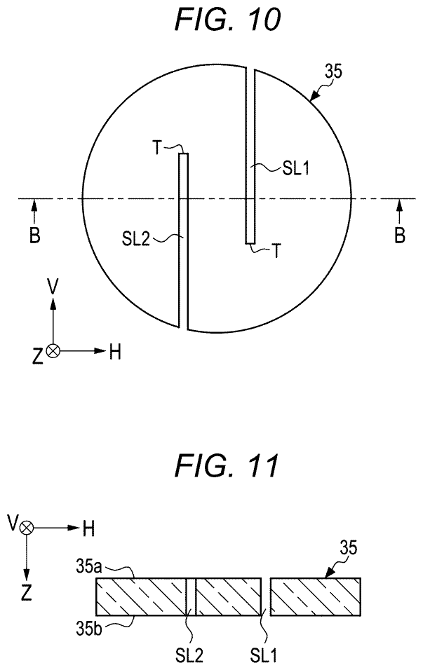

FIGS. 10 and 11 show the configuration of the OC 35 according to the first embodiment. FIG. 10 is a front view of the OC 35. FIG. 11 is a cross-sectional view of the OC 35 taken along the line B-B in FIG. 10. The OC 35 according to the present embodiment differs from that according to Comparative Example only in that at least one slit extending in the V direction is formed.

In the present embodiment, two slits SL1 and SL2 extending in the V direction and being separate from each other in the H direction are formed in the OC 35. That is, the slits SL1 and SL2 are parallel to each other in the longitudinal direction and are arranged in the widthwise direction perpendicular to the longitudinal direction.

In the present embodiment, the slits SL1 and SL2 each extend inward along the V direction from the outer edge of the OC 35, and an end T of the slit in the extending direction thereof is separate from the outer edge of the OC 35.

The slits SL1 and SL2 each pass through the OC 35 from a front surface 35a to a rear surface 35b. The width of each of the slits SL1 and SL2 in the H direction is preferably smaller than a width W of the irradiation spot S in the H direction. Note that the front surface 35a is an optical surface of the OC 35. In the present disclosure, the optical surface refers to a surface on which the pulse laser light PL is incident, and is a primary surface that performs the function of reflecting, transmitting, partially reflecting, or partially transmitting light.

In the present embodiment, the slits SL1 and SL2 extend in opposite directions, and the positions of the ends T differ from each other in the V direction. The slits SL1 and SL2 are 180° rotationally symmetric with respect to the center of the OC 35.

The slits SL1 and SL2 are each formed by performing grinding or ion beam processing on a substrate that constitutes the OC 35. In particular, using ion beam processing allows reduction in damage to the surface of the substrate during the processing.

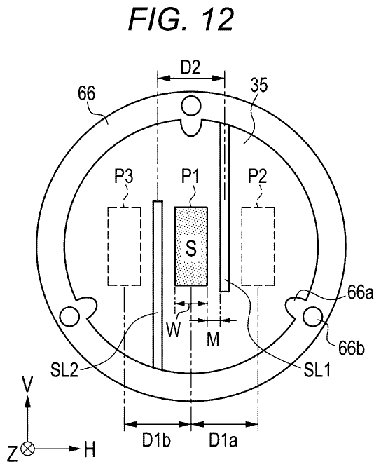

FIG. 12 shows the positional relationship of the slits SL1 and SL2 with the irradiation spot S. A distance D2 between the slits SL1 and SL2 is set to a value greater than the width W of the irradiation spot S in the H direction. Specifically, the distance D2 is preferably greater than the width W by 0.2 mm or more. A distance M from each of the slits SL1 and SL2 to the outer edge of the irradiation spot S is preferably greater than or equal to 0.1 mm and less than or equal to 5.0 mm. The thus set distances D2 and M are preferable in terms of extension of the operating life of the laser apparatus 2.

The first region P1 is set between the slit SL1 and the slit SL2. The second region P2 is set at a position separate from the first region P1 by the slit SL1. The third region P3 is set at a position separate from the first region P1 by the slit SL2. A distance D1a between the first region P1 and the second region P2 and a distance D1b between the first region P1 and the third region P3 are preferably equal to each other. The distances D1a and D1b are preferably equal to the distance D2.

Note that the slits SL1 and SL2 do not need to completely pass through the substrate that constitutes the OC 35, but the structure in which the two slits completely pass through the substrate is a desirable configuration because propagation of the damage can be suppressed more effectively.

### 2.2 Operation

The operation of the laser apparatus 2 according to the present embodiment is the same as that in Comparative Example except that the laser processor 100 controls the moving mechanism 64.

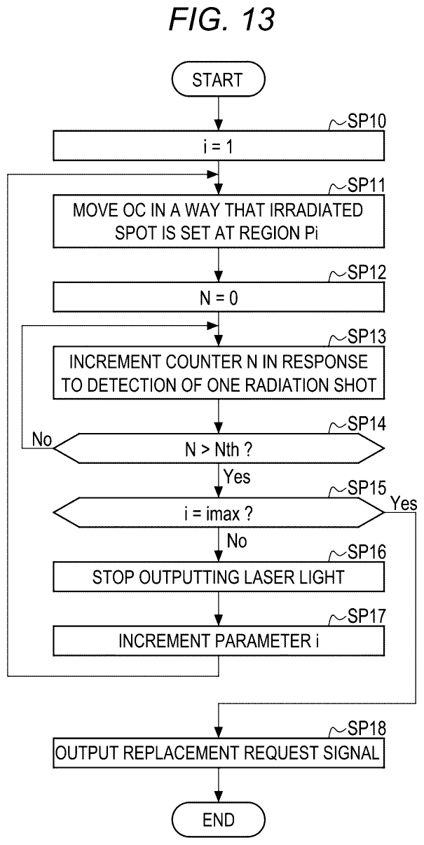

FIG. 13 shows the process procedure in which the laser processor 100 controls the moving mechanism 64. The laser processor 100 first sets a parameter i representing the position of the irradiation region to one (step SP10). The laser processor 100 next controls the moving mechanism 64 to move the OC 35 in the H direction so that the irradiation spot S is set at a region P1 (step SP11). Since i=1, the irradiation spot S is set at the first region P1.

The laser processor 100 next sets a counter N, which counts the number of radiation shots, to zero (step SP12). The laser processor 100 then increments the counter N in response to one radiation shot detected by the monitoring module described above (step SP13). The radiation shot refers to a radiation operation performed once on one irradiation region. One radiation shot may contain the pulse laser light PL configured with one pulse or multiple pulses.

The laser processor 100 next determines whether the count shown by the counter N is greater than a threshold Nth (step SP14). When the count shown by the counter N is less than or equal to the threshold Nth (No in step SP14), the laser processor 100 returns to the process in step SP13. When the count shown by the counter N becomes greater than the threshold Nth (Yes in step SP14), the laser processor 100 determines whether the parameter i is imax (step SP15). Note that imax is the number of the irradiation regions, which is three in the present embodiment.

When the parameter i is not imax (No in step SP15), the laser processor 100 stops outputting the laser light (step SP16) and increments the parameter i (step SP17). The laser processor 100 then returns to the process in step SP11. The laser processor 100 executes step SP11 again, so that the irradiation spot S is set at the second region P2. The laser processor 100 then carries out the same process.

When the parameter i becomes imax (Yes in step SP15), the laser processor 100 outputs a replacement request signal requesting replacement of the OC 35 to a display or the like that is not shown (step SP18), and terminates the process.

The process described above causes the irradiation spot S to be changed to the second region P2 when the number of radiation shots reaches the threshold Nth at the first region P1, and changed to the third region P3 when the number of radiation shots reaches the threshold Nth at the second region P2.

The irradiation spot S is moved from the first region P1 to the second region P2 across the slit SL1. The amount of movement from the first region P1 to the second region P2 is equal to the distance D2. The irradiation spot S is then moved from the second region P2 to the third region P3 across the slits SL1 and SL2. The amount of movement from the second region P2 to the third region P3 is equal to twice the distance D2.

The irradiation spot S is not necessarily moved in the order of the first region P1, the second region P2, and the third region P3, and may be moved in any order, for example, the third region P3, the first region P1, and the second region P2.

Furthermore, the moving mechanism 64 may be controlled by a processor that is not shown and differs from the laser processor 100.

### 2.3 Advantages

In the present embodiment, the OC 35 has at least one slit formed at the optical surface irradiated with the pulse laser light PL, and at least two irradiation regions set across the slit. The configuration described above prevents degradation having occurred at a certain irradiation region from expanding to another adjacent irradiation region.

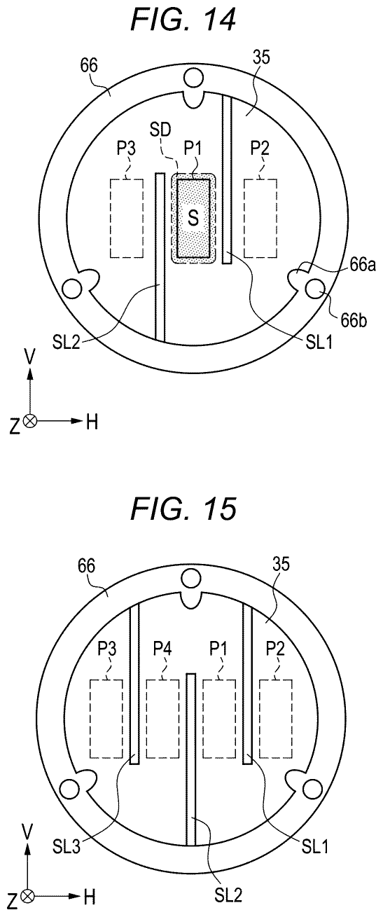

Specifically, the slit SL1 prevents the degraded region SD caused by the irradiation of the first region P1 with the pulse laser light PL from expanding to the second region P2, and the slit SL2 prevents further expansion to the third region P3, as shown in FIG. 14. The slits thus function as physical blockage of the propagation of the degradation. Since the irradiation regions are not degraded when the radiation starts, the number of radiation shots is not restricted by the influence of the degradation. The number of radiation shots that can be made in each of the irradiation regions can therefore be increased, so that the timing of the replacement of the OC 35 can be further delayed and in turn the operating life of the laser apparatus 2 can be further extended.

Furthermore, since the propagation of the degradation is blocked by the slits, the distance between two adjacent irradiation regions can be reduced. The number of the irradiation regions can thus be increased to four or more. For example, when three slits SL1 to SL3 are formed in the OC 35, first to fourth regions P1 to P4 can be set as four irradiation regions, as shown in FIG. 15. Increasing the number of the irradiation regions as described above allows further extension of the operating life of the laser apparatus 2. To increase the number of the irradiation regions, it is preferable to minimize the width of each of the slits.

In the present embodiment, the slits SL1 and SL2 are each formed so as to extend inward from the outer edge of the OC 35. The shape described above is highly workable particularly when a slit is formed by grinding, and is therefore preferable from the viewpoint of manufacturability. In addition, the end T of each of the slits SL1 and SL2 in the extending direction thereof is separate from the outer edge of the OC 35 and therefore does not completely divide the OC 35. The alignment of the OC 35 with respect to the optical path axis is therefore not complicated as compared with Comparative Example.

In the present embodiment, the slits SL1 and SL2 extend in opposite directions, and are 180° rotationally symmetric with respect to the center of the OC 35. The configuration described above can maintain the symmetry of the OC 35, and effectively suppress strain induced at the surface of the substrate when the slits are processed.

Note in the present embodiment that the OC 35 is exemplified as an optical element provided with at least one slit, but the present disclosure is not limited thereto, and providing a slit can be applied to various other optical elements in the laser apparatus 2. For example, providing a slit can be similarly applied to the rear mirror 31, the OC 17, the highly reflective mirrors 21a, 21b, 41, and 42, and the like.

### 2.4 Variations

Variations of the slit shape of the OC 35 will next be described.

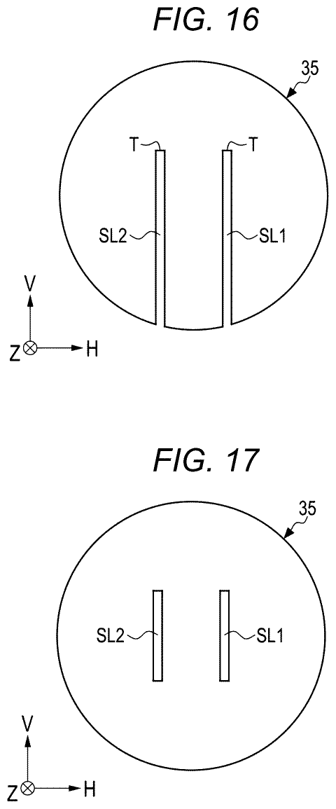

FIG. 16 shows the configuration of an OC 35 according to a first variation. In the present variation, the slits SL1 and SL2 each extend in the same direction from the outer edge of the OC 35, and the end T of each of the slits SL1 and SL2 in the extending direction thereof is separate from the outer edge of the OC 35. That is, the slits SL1 and SL2 extend in the same direction, and the ends T are located at the same position in the V direction. The other portions of the slits SL1 and SL2 are the same as those in the first embodiment.

In the present variation, the slits SL1 and SL2 are formed so as to extend from the outer edge of the OC 35 on one side. The configuration described above allows the slits to be readily processed particularly when the slits are formed by grinding, and therefore excels in manufacturability.

FIG. 17 shows the configuration of an OC 35 according to a second variation. In the present variation, the opposite ends of each of the slits SL1 and SL2 in the extending direction thereof are separate from the outer edge of the OC 35. In addition, the opposite ends of the slit SL1 are located at the same positions as those of the slit SL2 in the V direction. The other portions of the slits SL1 and SL2 are the same as those in the first embodiment.

The present variation, in which the length of each of the slits SL1 and SL2 is shorter than that in the first embodiment, is preferable in terms of reduction in processing period required for time-consuming ion beam processing. Furthermore, in the present variation, since the slits SL1 and SL2 are highly symmetrical, the strain induced at the surface of the substrate when the slits are processed can be effectively suppressed.

### 3. Second Embodiment

A laser apparatus 2 according to a second embodiment of the present disclosure will be described. In the present embodiment, at least one slit is formed in the BS 51. Note that elements that are the same as those described above have the same reference characters, and no redundant description of the same elements will be made unless otherwise they are particularly described.

### 3.1 Configuration

The laser apparatus 2 according to the present embodiment has the same configuration as the laser apparatus 2 according to Comparative Example except that the holder 81 and the BS 51 provided in the moving mechanism 80 are configured differently.

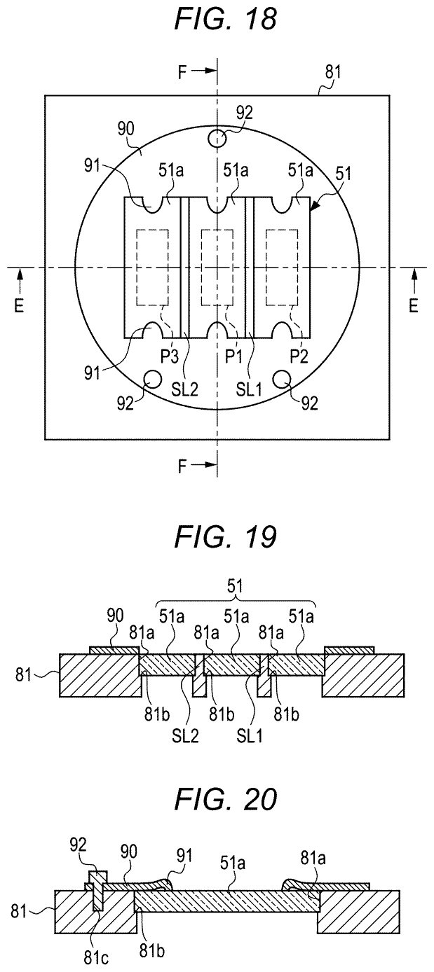

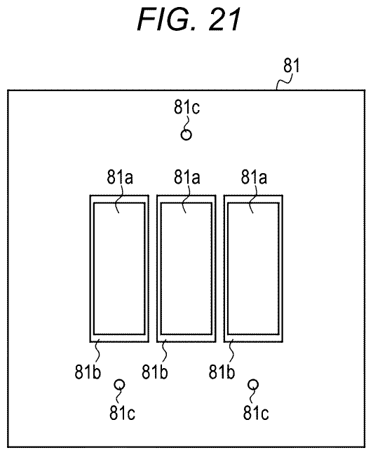

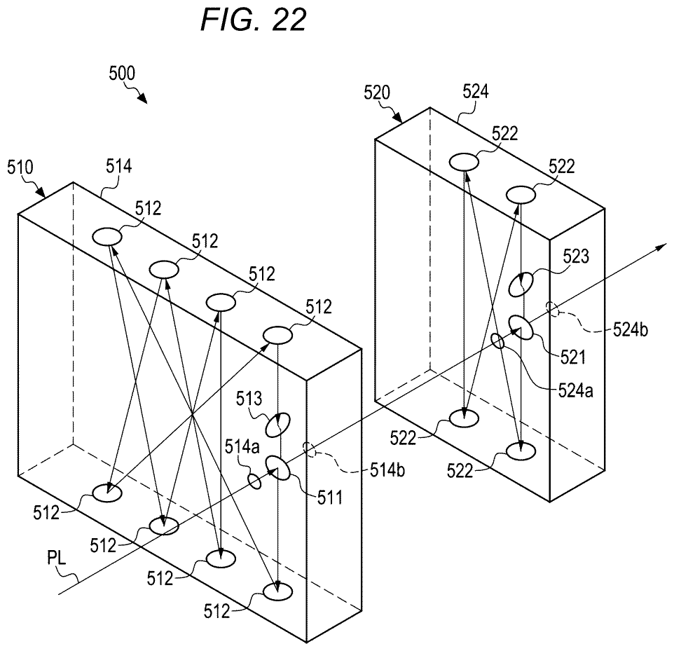

FIGS. 18 to 21 show the configuration of the holder 81 holding the BS 51 according to the second embodiment. FIG. 18 is a front view of the holder 81 holding the BS 51 according to the second embodiment. FIG. 19 is a cross-sectional view of the holder taken along the line E-E in FIG. 18. FIG. 20 is a cross-sectional view of the holder taken along the line F-F in FIG. 18. FIG. 21 is a front view of the holder 81.

In the present embodiment, the BS 51 is configured with three rectangular substrates 51a. Three rectangular openings 81a are formed in the holder 81, and the substrates 51a are fitted into the corresponding openings 81a. The openings 81a are each provided with an abutment surface 81b used to position the rear-surface-side outer edge of the substrate 51a. The abutment surfaces 81b provided at the openings 81a are all formed following a single reference plane. The multiple substrates 51a are thus arranged in the holder 81 at the same plane with high precision.

The three openings 81a are arranged in the holder 81 in the widthwise direction thereof. The three substrates 51a fitted into the openings 81a are disposed adjacent to each other in the widthwise direction via a partition wall located between two adjacent openings 81a. The partition wall functions as a region corresponding to a slit. That is, in the present embodiment, the three substrates 51a are arranged side by side with the partition wall interposed therebetween to form the two slits SL1 and SL2. That is, the slits SL1 and SL2 each divide the BS 51 in the present embodiment.

In the present embodiment, the leaf spring 90 is provided with multiple claws 91, which press down peripheral edge portions of the three substrates 51a. Specifically, two claws 91 are disposed in correspondence with opposite end portions of one substrate 51a in the longitudinal direction. The leaf spring 90 is attached to the holder 81 with three screws 92, and three screw holes 81c, into which the screws 92 are screwed, are formed in the holder 81.

The distance between the slits SL1 and SL2, the widths thereof, the positional relationship thereof with the irradiation spot S, and other factors are the same as those in the first embodiment.

### 3.2 Operation

The operation of the laser apparatus 2 according to the present embodiment is the same as that in the first embodiment. In the present embodiment, an irradiation region is set at each of the three substrates 51a. For example, the first region P1 is set at the central substrate 51a, the second region P2 is set at the right substrate 51a, and the third region P3 is set at the left substrate 51a. In the present embodiment, the position of the irradiation spot S is changed by manually operating the handle 87.

Also in the present embodiment, the moving mechanism 80 may be provided with an actuator, and the laser processor 100 may drive and control the actuator. How the laser processor 100 controls the moving mechanism 80 in this case is the same as that in the first embodiment. Note that the moving mechanism 80 may be controlled by a processor that is not shown and differs from the laser processor 100.

### 3.3 Advantages

According to the present embodiment, the timing of the replacement of the BS 51 can be delayed by the same advantageous effect provided by the first embodiment. The operating life of the entire laser apparatus 2 can thus be further extended.

In the present embodiment, in which the BS 51 is configured with the multiple substrates 51a, the flatness of the side surfaces of each of the substrates 51a can be improved by polishing the side surfaces. Therefore, even if part of the pulse laser light PL hits the edge of any of the slits, scatter of the light at the side surface is suppressed.

The BS 51 may have a configuration in which at least one slit that does not completely divide the substrate is formed in one substrate, as in the OC 35 according to the first embodiment. Note that the number of slits formed in the BS 51 is not limited to a specific number, and may be four or more.

### 4. Another Exemplary Form of OPS

FIG. 22 shows another exemplary form of the OPS. The OPS 50 shown in FIG. 1 may be replaced with a two-stage OPS 500. The OPS 500 includes a first OPS module 510 and a second OPS module 520.

The first OPS module 510 includes a BS 511, multiple concave mirrors 512, and a halving window 513, which are all disposed in a case 514. The case 514 has an entrance port 514a, via which the pulse laser light PL enters the case 514, and an exit port 514b, via which the pulse laser light PL exits out of the case 514. The multiple concave mirrors 512 constitute a looped optical path that circulates part of the pulse laser light PL incident via the entrance port 514a and reflected off the BS 511 and returns the circulated light to the BS 511.

The halving window 513 is a plane parallel substrate that is disposed between the final concave mirror 512 of the looped optical path and the BS 511 and corrects the looped optical path. Part of the pulse laser light PL incident from the halving window 513 on the BS 511 and reflected off the BS 511 passes through the exit port 514b and exits toward the second OPS module 520.

The second OPS module 520 includes a BS 521, multiple concave mirrors 522, and a halving window 523, which are all disposed in a case 524. The case 524 has an entrance port 524a, via which the pulse laser light PL enters the case 524, and an exit port 524b, via which the pulse laser light PL exits out of the case 524. The configuration of the second OPS module 520 is the same as that of the first OPS module 510 except that the number of the concave mirrors 522 differs from the number of the concave mirrors 512.

In addition, at least one slit may be formed in each of the halving windows 513 and 523, and two or more irradiation regions may be set across the slit as described above. Propagation of the degradation due to the radiation of the pulse laser light PL can thus be suppressed.

### 5. Electronic Device Manufacturing Method

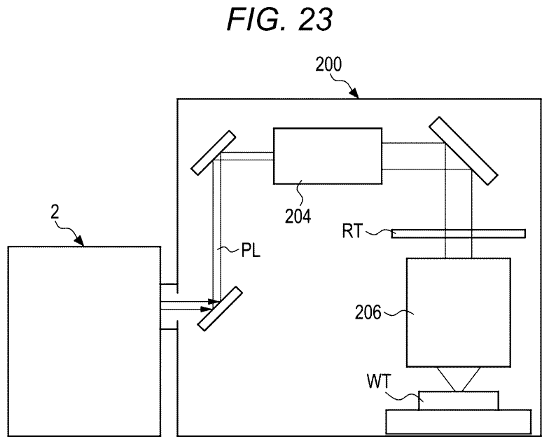

FIG. 23 schematically shows an example of the configuration of the exposure apparatus 200. The exposure apparatus 200 includes an illumination optical system 204 and a projection optical system 206. The illumination optical system 204 illuminates a reticle pattern of a reticle that is not shown but is placed on a reticle stage RT, for example, with the pulse laser light PL having entered the illumination optical system 204 from the laser apparatus 2. The projection optical system 206 performs reduction projection on the pulse laser light PL having passed through the reticle to bring the pulse laser light PL into focus at a workpiece that is not shown but is placed on a workpiece table WT. The workpiece is a photosensitive substrate onto which a photoresist has been applied, such as a semiconductor wafer.

The exposure apparatus 200 synchronously translates the reticle stage RT and the workpiece table WT to expose the workpiece to the pulse laser light PL having reflected the reticle pattern. Semiconductor devices can be manufactured by transferring the reticle pattern onto the semiconductor wafer in the exposure step described above and then carrying out multiple other steps. The semiconductor devices are an example of the “electronic devices” in the present disclosure.

### 6. Examples of Configuration of Laser Processor

A processor such as the laser processor 100 may be physically configured in the form of hardware to execute the various processes included in the present disclosure. For example, the processor may be a computer including a memory that stores a control program defining the various processes and a processing device that executes the control program. The control program may be stored in one memory, or may be stored separately in a plurality of memories at physically separate locations, and the various processes included in the present disclosure may be defined by a combination of control programs stored in the memories. The processing device may be a general-purpose processing device such as a CPU or a special-purpose processing device such as a GPU.

Alternatively, the processor may be programmed as software to execute the various processes included in the present disclosure. For example, the processor may be implemented in a dedicated device such as an ASIC or a programmable device such as an FPGA.

The various processes included in the present disclosure may be executed by one computer, one dedicated device, or one programmable device, or may be executed by cooperation of a plurality of computers, a plurality of dedicated devices, or a plurality of programmable devices at physically separate locations. The various processes may be executed by a combination including at least any two of: one or more computers, one or more dedicated devices, and one or more programmable devices.

The above description is intended not to be limiting but merely to be illustrative. It will therefore be apparent for a person skilled in the art that the embodiments of the present disclosure can be changed without departing from the accompanying claims.

The terms used throughout the present specification and the appended claims should be interpreted as non-limiting terms. For example, the term “include” or “included” should be interpreted as “is not limited to what is described as included”. The term “have” should be interpreted as “is not limited to what is described as having”. Furthermore, indefinite articles “a/an” described in the present specification and the appended claims should be interpreted to mean “at least one” or “one or more”. Further, “at least one of A, B, and C” should be interpreted to mean any of A, B, C, A+B, A+C, B+C, and A+B+C as well as to include combinations of any thereof and any other than A, B, and C.

What is claimed is:

1. A laser apparatus comprising:
an oscillator configured to output pulse laser light;
an optical element disposed in an optical path of the pulse laser light and having at least one slit formed in a surface irradiated with the pulse laser light; and
a moving mechanism configured to move the optical element.

2. The laser apparatus according to claim 1, further comprising:
an amplifier configured to amplify the pulse laser light,
wherein the optical element is a mirror provided in an optical resonator of the amplifier.

3. The laser apparatus according to claim 1, wherein
the optical element is a mirror provided in an optical resonator of the oscillator.

4. The laser apparatus according to claim 1, wherein
the optical element is a beam splitter disposed outside the oscillator.

5. The laser apparatus according to claim 4, wherein
the beam splitter is provided in an optical pulse stretcher.

6. The laser apparatus according to claim 1, wherein
the at least one slit includes multiple slits extend parallel to each other in a longitudinal direction and arranged in a direction perpendicular to the longitudinal direction.

7. The laser apparatus according to claim 6, wherein
the moving mechanism is configured to move the optical element in the direction perpendicular to the longitudinal direction.

8. The laser apparatus according to claim 6, wherein
a distance between the multiple slits is greater than a width of an irradiation spot of the pulse laser light radiated to the optical element by 0.2 mm or more.

9. The laser apparatus according to claim 6, wherein
a distance from each of the multiple slits to an outer edge of an irradiation spot of the pulse laser light radiated to the optical element is greater than or equal to 0.1 mm and less than or equal to 5.0 mm.

10. The laser apparatus according to claim 6, wherein
the multiple slits each extend inward from an outer edge of the optical element, and an end of each of the multiple slits in an extending direction thereof is separate from the outer edge of the optical element.

11. The laser apparatus according to claim 10, wherein
two adjacent slits of the multiple slits extend in opposite directions.

12. The laser apparatus according to claim 10, wherein
two adjacent slits of the multiple slits extend in the same direction.

13. The laser apparatus according to claim 6, wherein
opposite ends of each of the multiple slits in an extending direction thereof are separate from an outer edge of the optical element.

14. The laser apparatus according to claim 6, wherein
the multiple slits each divide the optical element.

15. The laser apparatus according to claim 6, wherein
a width of each of the multiple slits is less than a width of an irradiation spot of the pulse laser light radiated to the optical element.

16. The laser apparatus according to claim 1, further comprising
a processor,
wherein the moving mechanism includes an actuator, and
the processor is configured to cause a first region of the optical element to be irradiated with the pulse laser light, and then control the moving mechanism to move the optical element in a way that a second region separated from the first region by the at least one slit is irradiated with the pulse laser light.

17. An irradiation method using a laser apparatus including
an oscillator configured to output pulse laser light,
an optical element disposed in an optical path of the pulse laser light and having at least one slit formed in a surface irradiated with the pulse laser light, and
a moving mechanism configured to move the optical element, the method comprising:
irradiating a first region of the optical element with the pulse laser light;
controlling the moving mechanism to move the optical element in a way that a second region separated from the first region by the at least one slit is irradiated with the pulse laser light; and
irradiating the second region with the pulse laser light.

18. An electronic device manufacturing method comprising:
outputting pulse laser light from a laser apparatus to an exposure apparatus; and
exposing a photosensitive substrate to the pulse laser light in the exposure apparatus to manufacture electronic devices,
the laser apparatus including an oscillator configured to output the pulse laser light,
an optical element disposed in an optical path of the pulse laser light and having at least one slit formed in a surface irradiated with the pulse laser light, and
a moving mechanism configured to move the optical element.
